(19) United States
(12) Patent Application Publication
(10) Pub. No.: US 2014/0130846 A1
(43) Pub. Date: May 15, 2014

(54) Electric power generation and heating system using solar energy

(71) Applicants: Oh-sung KWON, Chilgok-gun (KR); Yeong-Chun Jun, Seoul (KR); Young-min Jeon, Changwon-si (KR)

(72) Inventors: Oh-sung KWON, Chilgok-gun (KR); Yeong-Chun Jun, Seoul (KR); Young-min Jeon, Changwon-si (KR)

(21) Appl. No.: 14/078,639

(22) Filed: Nov. 13, 2013

(30) Foreign Application Priority Data
Nov. 13, 2012 (KR) 10-2012-0129119

(51) Int. Cl. H01L 31/0525

(52) U.S. Cl. CPC H01L 31/058
USPC 136/248

(57) ABSTRACT

The electric power generation and heating system using solar energy is disclosed, which comprises a solar cell module; a heat collection part; a heat exchange storage tank; a turbine part; a generator generating electric power; a condenser; a heating part; a water supply pump; and a battery.

### TECHNICAL FIELD

The present invention relates to an electric power generation and heating system using solar energy which has features in that an electric power is generated using a solar cell and a solar heat collection rod, and the generated electric power is used so as to heat and cool a building, and the electric power generated using a solar energy and a solar heat can be used as an electric power for heating and cooling at night or when it rains. More specifically, a solar energy is converted into an electric energy using semiconductors, and a solar heat collection rod serves to collect heat and store solar energy for thereby generating electric energy using a turbine and a generator or a collected heat energy can be directly supplied so as to heat or cool a building.

### BACKGROUND ART

The Korean patent registration number 10-1079642 discloses a technology which is similar with the features of the present invention. FIG. 1 is a view illustrating a construction of a heating system using a solar heat and a sunshine-based power generation. As shown therein, the heating system using a solar heat and a sunshine-based power generation comprises a basic unit 100 which is installed on an outer wall of a building and serves to receive solar heat and to provide a greenhouse effect. A transparent window 120 is installed outside the basic unit 100 for receiving sunshine into the basic unit 100. A black heat absorption panel 110 is provided at an indoor side of the basic unit 100 for efficiently converting the sunshine inputted into the basic unit 100 into energy form. At the heat absorption panel 110 is formed an inlet hole 111 through which indoor air is inputted. An outlet hole 113 is provided so as to heat the indoor air inputted into the basic unit 100 and discharge the heated indoor air into the indoor. Since the air of temperature lower than the temperature of the basic unit 100 is inputted into the inlet hole 111, the inlet hole 111 is formed at a lower side, and since the air of temperature higher than the indoor temperature is discharged via the outlet hole 113, the outlet hole 113 is formed at an upper side, the construction of which is directed to enhancing natural convection. Here, the basic unit 100 is formed in a cubic box shape. The transparent window 120 is made from transparent vinyl, glass, acryl panel, etc. The heat absorption panel 110 serves to absorb solar heat, so it may be coated in a black color or may be made from a back color material. A rim 130 serving to support the box is made from a synthetic resin or a metallic material. Here, the black color material may be PVA (Polyvinyl Alcohol), and the basic unit 100 is designed to have a function of inputting or discharging indoor air based on natural convection or to have a forced blowing function.

### DISCLOSURE OF THE INVENTION

Accordingly, it is an object of the present invention to provide an electric power generation and heating system using solar energy which overcomes the problems encountered in the conventional art in which a heat collection efficiency is bad because of the use of a flat solar heat absorption panel.

It is another object of the present invention to provide an electric power generation and heating system using solar energy which overcomes the problems encountered in the conventional art in which an energy application efficiency is bad because a conventional heating system using a solar heat and a solar heat-based generation uses solar energy only for the sake of heating system.

It is further another object of the present invention to provide an electric power generation and heating system using solar energy which makes it possible to use in maximum solar energy by enhancing a collection efficiency of solar energy.

It is still further another object of the present invention to provide an electric power generation and heating system using solar energy which makes it possible to efficiently generate electric power at night and when it rains in such a way to store a solar energy-based electric power in a battery and to use the stored electric power as a driving force source of a storage tank.

To achieve the above objects, there is provided an electric power generation and heating system using solar energy which comprises a solar cell module configured to convert solar energy into electric energy; a heat collection part formed of a plurality of heat collection rods designed to collect heat from the solar energy; a heat exchange storage tank which is equipped with a heating part which generates heat from the electric energy from the solar cell module and stores fluid as a heat medium oil containing heat collected from the solar heat collection part performs a heat exchange while it flows via a tube; a turbine part into which to receive vapor generated from the fluid stored in the heat exchange storage tank for thereby rotating the turbine; a generator generating electric power as the turbines of the turbine part rotate; a condenser serving to collect and condense the vapor which has been used for rotating the turbines in the turbine part; a heating part which helps heat the building using the fluid condensed by the condenser; a water supply pump which serves to collect the fluid whose temperatures was lowered through the heating procedures by the heating part of the building and transfers the collected fluid to the heat exchange storage tank; and a battery which serves to store the electric power generated by the generator and is electrically connected to the heating part. With the above elements, a circulation cycle system is configured, thus efficiently using solar energy.

### Advantageous Effects

The electric power generation and heating system using solar energy according to the present invention has advantageous effects in that the solar energy can be used in maximum. As another advantageous effect, the use of fossil energy can be reduced. The solar energy is environment friendly, and the productions of carbon dioxide and carbon monoxide can be reduced. Since the electric power generated by the generator can be used as an energy source of the heat exchange tank, it is possible to efficiently use the heat exchange tank even when the solar energy is not available at night or when it rains.

### BRIEF DESCRIPTION OF THE DRAWINGS

The present invention will become better understood with reference to the accompanying drawings which are given only by way of illustration and thus are not limitative of the present invention, wherein;

FIG. 1 is a view illustrating a construction of a conventional heating system using solar heat and a solar energy-based power generation;

FIG. 2 is a view illustrating the whole constructions of an electric power generation and heating system using solar energy according to the present invention;

FIG. 3 is a perspective view illustrating a solar heat collection rod according to the present invention;

FIG. 4 is a disassembled perspective view illustrating a solar heat collection rod according to the present invention;

FIG. 5 is a cross sectional view illustrating a solar heat collection rod according to the present invention;

FIG. 6 is a horizontal cross sectional view illustrating a solar heat collection rod according to the present invention; and

FIG. 7 is a cross sectional view illustrating a solar heat collection means according to the present invention.

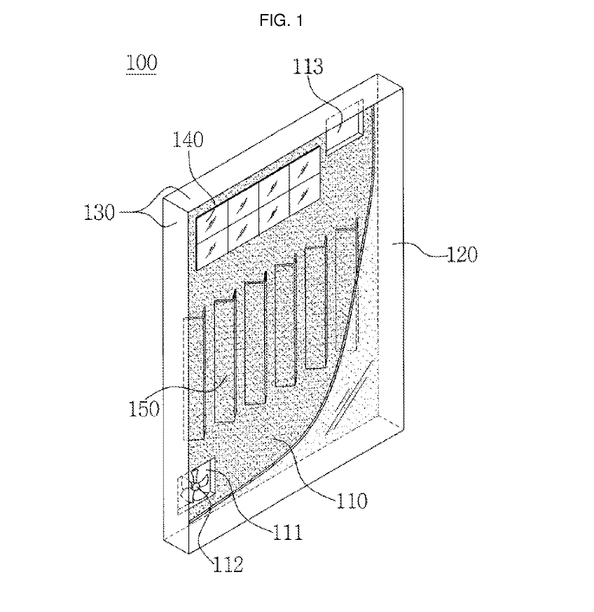

### MODES FOR CARRYING OUT THE INVENTION

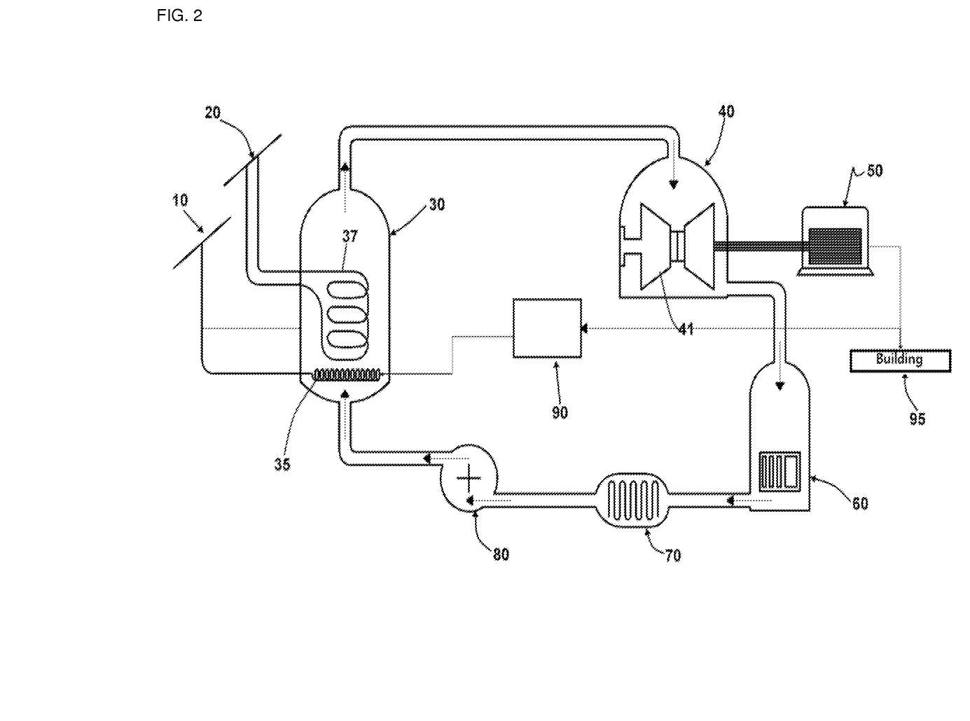

The electric power generation and heating system using solar energy according to the present invention will be described with reference to FIGS. 2 to 7.

FIG. 2 is a view illustrating the whole constructions of an electric power generation and heating system using solar energy according to the present invention. As shown in FIG. 2, the electric power generation and heating system using solar energy according to the present invention comprises a solar cell module 10 configured to convert solar energy into electric energy; a heat collection part 20 formed of a plurality of heat collection rods designed to collect heat from the solar energy; a heat exchange storage tank 30 which is equipped with a heating part which generates heat from the electric energy from the solar cell module 10 and stores fluid as a heat medium oil containing heat collected from the solar heat collection part 20 performs a heat exchange while it flows via a tube 37; a turbine part 40 into which to receive vapor generated from the fluid stored in the heat exchange storage tank 40 for thereby rotating the turbine 41; a generator 50 generating electric power as the turbines of the turbine part 40 rotate; a condenser 60 serving to collect and condense the vapor which has been used for rotating the turbines in the turbine part 40; a heating part 70 which helps heat the building using the fluid condensed by the condenser 60; a water supply pump 80 which serves to collect the fluid whose temperatures was lowered through the heating procedures by the heating part 70 of the building and transfers the collected fluid to the heat exchange storage tank; and a battery 90 which serves to store the electric power generated by the generator 50 and is electrically connected to the heating part. The electric power generated from the generator 50 may be stored in the battery 90 and may be used so as to heat the heating part 35. The surplus electric power after the battery 90 is charged may be used as an energy source for lighting, etc.

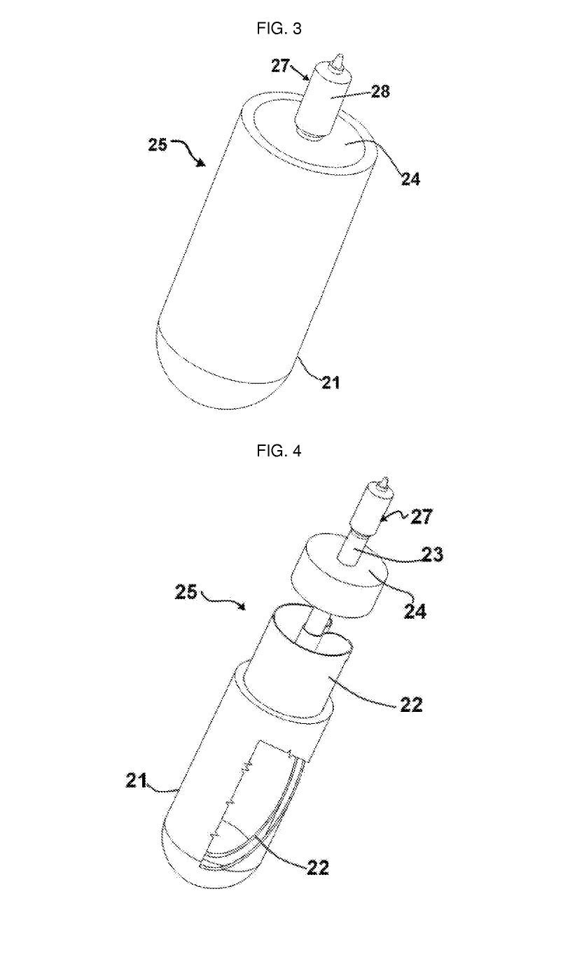

FIG. 3 is a perspective view illustrating a solar heat collection rod according to the present invention. As shown therein, the solar heat collection rod 25 of the present invention comprises a heating rod support shaft 23 inserted into a heat collection rod support part 22 inserted in a heat collection rod body 21; a cover 24 which is inserted in the support shaft 23 and covers the interior of the heat collection rod body 21; and a heating rod 27 which is inserted into the end portion of the heating rod support shaft 23 inserted in the cover 24. The heating rod body 28 may be formed in various shapes such as a cylindrical shape, a quadrangle shape or a polygonal shape.

FIG. 4 is a disassembled perspective view illustrating a solar heat collection rod according to the present invention. As shown therein, the solar heat collection rod 25 comprises a heat collection rod body 21 whose bottom is rounded; a heat collection rod support part 22 inserted into the heat collection rod body 21; a heating rod support shaft 23 inserted into the center of the heat collection rod part 22; a cover 24 which is inserted in the heating rod support shaft 23 and seals the interior of the heat collection rod boy 21; and a heating rod 27 which is engaged, at the top of the cover 24, to the heating rod support shaft 23.

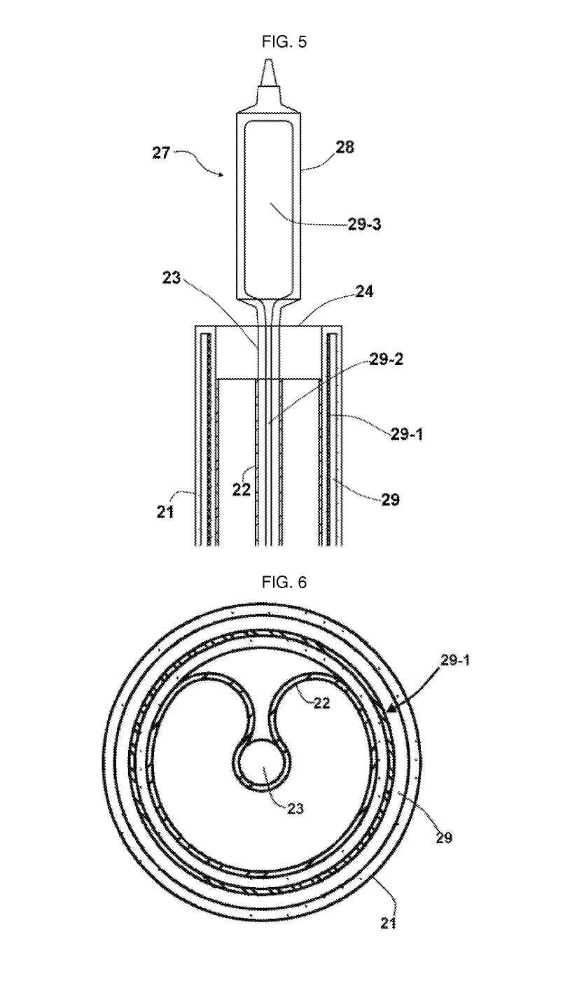

FIG. 5 is a cross sectional view illustrating a solar heat collection rod according to the present invention. As shown therein, the solar hear collection rod 25 according to the present invention comprises a heat collection rod 21 which comprises a space part 29 which is formed inside and is a sealed space and a film 29-1 on which is coated a ceramic and carbon attached on the surfaces of the space part 29, the bottom of the heat collection rod body 21 being sealed; a heat collection support part 22 which is inserted into the interior of the space part 29 formed at the inner side of the heat collection rod body 21; a heating rod support shaft 23 which is inserted into the center of the heat collection rod support part 22 and a second space part 29-2 formed at an inner side and filled with Freon gas; a cover 24 which is inserted into the heating rod support shaft 23 and is air-tightly installed at the top end of the heat collection rod body 21 and is made from asbestos; and a heating rod 27 which is integrally engaged to the heating rod support shaft 23 and has a third space part 29-3 communicating with the second space part 29-2 of the heating rod support shaft 23 and is made from an alloy of cast iron and silver. The thusly configured heat collection rod 25 has features in that the film 29-1 coated on one surface of the space part 29 in the heat collection rod body 21 when solar heat is input into the heat collection rod body 21 comes to efficiently absorb solar heat, thus heating Freon gas filed in the second space part 29-2 of the heating rod support shaft 23. The heated Freon gas whose temperature is high ascends and is filled into the third space part 29-3 of the heating rod 27. Sunshine can well transmit the outer surface of the heat collection rod body 21 of the heating rod 25 which is made from glass.

FIG. 6 is a horizontal cross sectional view illustrating a solar heat collection rod according to the present invention. As shown therein, the solar heat collection rod 25 comprises a sealed space part 29 at the inner side of the heat collection rod body 21, and a film 29-1 is attached to one surface of the space part 29. Into the inner side of the space part 29 of the heat collection rod body 21 is inserted a U-shaped heat collection support part 22 which forms a closed circuit. Into the center of the heat collection rod support part 22 is inserted a heating rod support shaft 23.

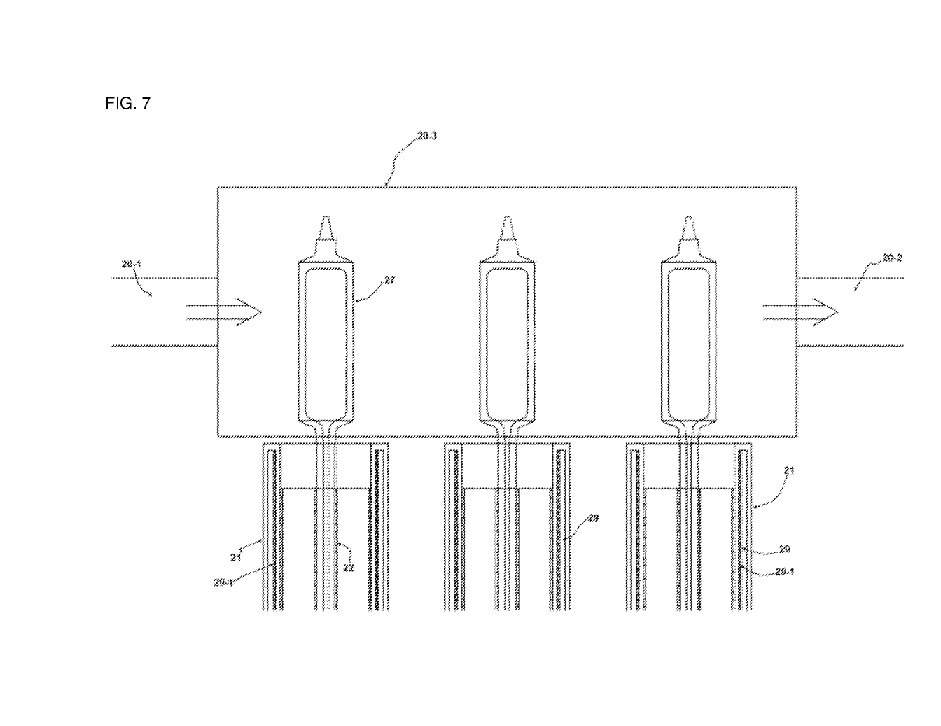

FIG. 7 is a cross sectional view illustrating a solar heat collection means according to the present invention. As shown therein, the solar heat collection means 20 according to the present invention comprises a heat collection tank 20-3 in which heat medium oil flows through an inlet port 20-1 and an outlet port 20-2. The heating rod 27 is inserted into the interior of the heat collection tank 20-3. The heat collection rod body 21 comprises a plurality of heat collection rods 25 which are installed being exposed from the heat collection tank 20-3. Here, the heat medium oil is inputted into the heat collection tank 20-3 via the inlet port 20-1 of the heat collection tank 20-3 and is heated by the head radiating from the heating rod 27 of the heat collection rod 25 and is inputted into the heat exchange storage tank 30 via the outlet port 20-2. In addition, sunshine is inputted into the outer sides of the heat collection body 21 which is exposed from the lower side of the heat collection tank 20-3 and whose outer layer is made from glass. The film 29 attached to the inner sides of the body of the heat collection rod 21 effectively absorbs the solar energy for thereby heating Freon gas filled in the second space part 29-2 in the heating rod support shaft 23 inside the heat collection rod body 21. The heated Freon gas ascends into the third space part 29-3 of the heating rod 27 in the interior of the heat collection tank 20-3 for thereby heating the heat medium oil inputted via the inlet port 20-1 of the heat collection tank 20-3. The Freon gas whose temperature was lowered after it heated the heat medium oil is liquefied and descends into the second space part 29-2 of the body of the heat collection rod 25 and absorbs the solar heat again, the cycles of which are repeatedly performed.

The electric power generation and heating system using solar energy according to the present invention can help reduce energy consumption while effectively using the solar energy.

What is claimed is:

1. An electric power generation and heating system using solar energy, comprising:
a solar heat collection rod which collects solar heat and comprises:
a heat collection rod body;
a heat collection rod support part which is inserted into an inner side of a space part formed at an inner side of the heat collection rod body;
a heat rod support shaft which is inserted into the center of the heat collection rod support part and has a second space part formed in the interior;
a cover which is inserted into the heating rod support shaft and seals the top end of the heat collection rod body; and
a solar heat collection rod which is integrally engaged to the heating rod support shaft and has a third space part communicating with the second space part of the heating rod support shaft.

2. The system of claim 1, wherein a film is attached to one surface of the space part.

3. The system of claim 1, wherein Freon gas is filled in the second space part.

4. The system of claim 1, wherein the cover is made from asbestos.

5. The system of claim 1, wherein the outer layer of the heat collection rod body is made from glass.

6. The system of claim 2, wherein the film is coated with ceramic and carbon.

7. The system of claim 2, wherein the heating rod and the heating rod support shaft are made from an alloy of cast iron and silver.
